(19) United States
(12) Patent Application Publication
(10) Pub. No.: US 2026/0163474 A1
(43) Pub. Date: Jun. 11, 2026

(54) ELECTRONIC PRODUCT PACKAGE FOR NOISE CORRECTION

(71) Applicant: MOTIVELINK CO.,Ltd, Yongin-si (KR)

(72) Inventors: Dong Won LEE, Yongin-si (KR); Sung Hwan AN, Yongin-si (KR); Hyun Yong JOO, Gwangju-si (KR); Seon Yeong JUNG, Yongin-si (KR)

(73) Assignee: MOTIVELINK CO.,Ltd, Yongin-si (KR)

(21) Appl. No.: 19/300,560

(22) Filed: Aug. 14, 2025

Related U.S. Application Data
(63) Continuation of application No. PCT/KR2023/006492, filed on May 12, 2023.

(30) Foreign Application Priority Data
Feb. 14, 2023 (KR) 10-2023-0019588
May 11, 2023 (KR) 10-2023-0061310

(51) Int. Cl. H02M 1/42; H02M 1/44; H05K 5/02

(52) U.S. Cl. CPC H02M 1/42; H02M 1/44; H05K 5/02

(57) ABSTRACT

The present invention relates to an electronic product package and, more specifically, to an electronic product package for noise correction, which maximizes the efficiency of power supplied to an electronic device. The electronic product package for noise correction according to an embodiment disclosed in the present invention comprises: a PFC unit which improves a power factor of external power supplied from the outside; a capacitor module which transfers the external power to the PFC unit and cancels noise occurring in the process of transferring the external power; and a casing which accommodates the PFC unit and the capacitor module to form an integrated package.

### TECHNICAL FIELD

The present disclosure relates to an electronic product package, and more particularly, to an electronic product package for noise correction, which maximizes efficiency of power supplied to an electronic device and corrects noise.

### BACKGROUND ART

Power that is produced from a power production facility such as a power plant is supplied to facilities (e.g., industrial facilities and houses) that require the power through a power line, etc.

In this case, alternating current (AC) power of the produced power needs to be converted into a direct current (DC) in order to be used in the electronic device. In order to maximize efficiency of DC power that is used in the electronic device, a component for power factor correction and noise correction may be disposed within the electronic device.

In general, a PFC inductor is proposed as a component for power factor correction. A PFC inductor according to an embodiment functions to maximize power conversion efficiency by minimizing a power loss that occurs when AC power input to an electronic device is converted into DC power and used. The PFC inductor is a kind of boost inductor disposed behind a filter (e.g., a noise filter) in the entire power system, and is one of components, which generates a lot of heat in an electronic product having a relatively large capacity. Accordingly, if the PFC inductor is used in an electronic device, an electronic product is designed and disposed so that heat dissipation is easily performed by attaching heat dissipation silicon, etc. is attached around the PFC inductor so that the inductor is closely attached to an external case. Thereafter, a capacitor for removing electromagnetic wave noise, etc. may be additionally disposed at a proper location based on the results of tests of electromagnetic interference (EMI).

If the capacitor is additionally disposed, an overall size of the electronic product may be increased because a predetermined space is additionally required on a circuit board. Furthermore, there is a problem in that a space for accommodating the capacitor needs to be separately provided or a path for removing noise removal needs to be separately formed.

### DISCLOSURE

### Technical Problem

In order to solve the problems, a disclosed embodiment of the present disclosure provides an electronic product package for noise correction, which minimizes an occupied space because a PFC part and a capacitor module are integrated into a single package.

Furthermore, a disclosed embodiment of the present disclosure provides an electronic product package for noise correction, which forms a noise removal path because at least a part thereof is formed of a thermal-conductive and electrical-conductive material.

Furthermore, a disclosed embodiment of the present disclosure provides an electronic product package for noise correction, including a wire accommodation and guide unit in which a capacitor arrangement board is disposed instead of a PCB on which a pattern for electrical conduction and signals has been printed and that extends at a predetermined distance from one side of the capacitor arrangement board.

Objects of the present disclosure are not limited to the aforementioned objects, and the other objects not described above may be evidently understood from the following description by those skilled in the art.

### Technical Solution

An electronic product package for noise correction according to a disclosed embodiment of the present disclosure includes a PFC part that improves a power factor of external power that is supplied from an outside, a capacitor module that transfers the external power to the PFC part and that removes noise occurring in a process of the external power being transferred, and a casing that forms an integrated package by accommodating the PFC part and the capacitor module.

Furthermore, the PFC part may include at least one PFC inductor. One end of the PFC inductor is connected to a filter circuit through at least a part of the capacitor module. The other end of the PFC inductor may be connected to at least one output terminal on a side different from a side of the capacitor module on the basis of the PFC inductor.

Furthermore, the capacitor module may include at least one capacitor corresponding to the PFC inductor. The capacitor may be disposed between the filter circuit and the PFC part, and may remove noise occurring due to the external power transferred through the filter circuit.

Furthermore, the casing may include a first casing that may be made of a first material and that forms an external surface of the casing and a second casing that is made of second material different from the first casing and that is accommodated within the first casing so that an external surface of the second casing comes into contact with an internal surface of the first casing.

Furthermore, the first material may be an electrically conductive material. The first casing may be electrically connected to the capacitor module and forms a noise movement path.

Furthermore, the capacitor module may further include an elastic contact point that has one end electrically connected to the capacitor and the other end electrically connected to the internal surface of the first casing and that forms at least a part of the noise movement path.

Furthermore, the elastic contact point may include a plane part formed by extending from one side of a PCB on which the capacitor is disposed at a predetermined length in one direction and a curved part formed by extending from one end of the plane part and having a curved shape. The curved part may be assembled into the casing and pressurized by the internal surface of the first casing.

Furthermore, the second casing may include a PFC part accommodation part for accommodating the PFC part and a capacitor module accommodation part that is formed on one side of the PFC part accommodation part and that accommodates at least a part of the capacitor module.

Furthermore, the PFC part accommodation part may include a PFC inductor accommodation space corresponding to the number of PFC inductors.

Furthermore, the PFC inductor may be provided in a plural number. The PFC part accommodation part may further include at least one inductor barrier rib part that separates the PFC inductors.

Furthermore, the capacitor module may include a PCB on which the capacitor is installed. The PCB may be disposed in a direction in which the PCB is mutually perpendicular to a main PCB that is electrically connected to the output terminal.

Furthermore, the capacitor module may include a wire accommodation part that is fixed to one side of the PCB and that accommodates a first connection part that enables the PFC inductor to be connected to the capacitor module. The wire accommodation part may include a wire cover part having a constant thickness and a hollow structure in order to cover at least a part of an external surface of the first connection part and a wire guide part that is formed by protruding from one surface of the wire cover part at a predetermined length, that is fixed to the PCB, and that guides the first connection part.

Furthermore, the second casing may further include a PCB accommodation part depressed and formed at a constant depth. One end of the PCB may be slid, assembled, and fixed to the PCB accommodation part.

Furthermore, the capacitor module may include a capacitor arrangement board in which the capacitor is disposed. The capacitor arrangement board may be disposed in a direction in which the capacitor arrangement board is mutually perpendicular to a main PCB that is electrically connected to the output terminal.

Furthermore, the capacitor module may include a wire accommodation and guide unit that is formed by extending from one side of the capacitor arrangement board at a predetermined length and that accommodates and guides a first connection part that enables the PFC inductor to be connected to the capacitor module. The wire accommodation and guide unit may include a wire support part that is formed by protruding from the one side of the capacitor arrangement board at a predetermined first height in order to support at least a part of an external surface of the first connection part and a pair of wire anti-breakaway parts that is formed by protruding upward from a top of the wire support part at a predetermined second height, that is fixed to the capacitor arrangement board, and that guides the first connection part.

Furthermore, the wire accommodation and guide unit may further include a lead accommodation part that is formed by extending from a side opposite to the wire anti-breakaway part in the wire support part and that is formed by protruding from one surface of the capacitor arrangement board at a predetermined length. The lead accommodation part may include at least one lead accommodation hole that accommodates the lead of the capacitor or has the lead penetrate therethrough.

Furthermore, the capacitor arrangement board may include a first board step part that has a first board width and has the capacitor disposed on one surface side thereof and a second board step part that has a second board width smaller than the first board width and that is formed by protruding from the other surface side opposite to one surface side that belongs to the first board step part and in which the capacitor is disposed at a predetermined thickness.

Furthermore, the first board step part may have both ends accommodated in a board accommodation part that is depressed and formed in the second casing of the casing at a constant depth in a width direction thereof. The second board step part has both ends accommodated in an internal surface of the second casing in a width direction thereof.

Furthermore, the capacitor module may further include an elastic contact point that has one end electrically connected to the capacitor and the other end electrically connected to the internal surface of the first casing of the casing and forms at least a part of a noise movement path. The elastic contact point may include a common lead accommodation part that is formed by being combined with one surface side of the capacitor arrangement board and that accommodates the lead of the capacitor in common.

### Advantageous Effects

According to a proposed embodiment, the electronic product package for noise correction according to a disclosed embodiment of the present disclosure has an advantage in that stable power that enables an electronic device to operate can be supplied because noise correction is performed in a process of power being transferred.

Furthermore, there is an advantage in that noise is easily removed because the capacitor module is disposed between the filter circuit and the PFC part.

Furthermore, there is an advantage in that the electronic product package according to a disclosed embodiment of the present disclosure is integrated and reduced in size because the casing forms an integrated package by accommodating the PFC part and the capacitor module.

Furthermore, there are advantages in that a space of the capacitor module, which is occupied in the casing, can be minimized and the electronic product package for noise correction according to a disclosed embodiment of the present disclosure is reduced in size because the PCB on which the capacitor is disposed in the capacitor module is disposed in the direction perpendicular to the direction in which the main PCB is disposed.

Furthermore, there is an advantage in that stable noise removal is possible because at least a part (more specifically, the first casing) of the casing forms a noise movement path through the elastic contact point.

Furthermore, there are advantages in that a manufacturing cost is reduced and stable noise removal is also possible because the capacitor arrangement board is used instead of a PCB and a noise movement path is formed through the wire accommodation and guide unit combined with the capacitor arrangement board and the elastic contact point.

Furthermore, there is an advantage in that the first connection part can be stably connected to the input terminal because at least a part of the first connection part is accommodated and guided by the wire accommodation and guide unit.

Furthermore, there are advantages in that the capacitor arrangement board can be properly disposed at a constant location within the casing and the stability of the electronic product package for noise correction is improved because both ends of the first board step part of the capacitor arrangement board in the width direction thereof are accommodated in the board accommodation part of the second casing and both ends of the second board step part in the width direction thereof are accommodated in the internal surface of the second casing.

### DESCRIPTION OF DRAWINGS

FIG. 1 is a perspective view of an electronic product package for noise correction according to a disclosed embodiment of the present disclosure.

FIG. 2 is for describing a flow of a current and a location where a capacitor is disposed in the electronic product package for noise correction of FIG. 1.

FIG. 3 is a top view of the electronic product package for noise correction according to FIG. 1.

FIG. 4 is for describing a relation between a main PCB on which the electronic product package for noise correction is seated and a PCB on which the capacitor is seated in FIG. 1.

FIG. 5 is a cross-sectional view taken along line A-A′ in FIG. 1.

FIG. 6 is for describing a capacitor module, that is, one component of the electronic product package for noise correction according to a disclosed embodiment of the present disclosure.

FIG. 7 is for describing a path from which noise is removed though at least a part of the capacitor module of FIG. 6 and the casing.

FIG. 8 is for describing a path from which noise is removed.

FIG. 9 is for describing the casing that accommodates the PFC part and the capacitor module in the electronic product package for noise correction according to a disclosed embodiment of the present disclosure.

FIG. 10 is for describing the capacitor module, that is, one component of an electronic product package for noise correction according to another embodiment of the present disclosure.

FIG. 11 is the side of the capacitor module, that is, one component of the electronic product package for noise correction according to another embodiment of the present disclosure.

### LIST OF REFERENCE NUMERALS

1, 2: electronic product package for noise correction
100: PFC part 110, 120, 130: PFC inductor
200, 200′: capacitor module 210: capacitor
220: PCB 230: elastic contact point
220′: capacitor arrangement board 250′: wire accommodation and guide unit
300: casing 310: first casing
320: second casing 600: filter circuit
700: main PCB

### Best Mode

Advantages and characteristics of the present disclosure and a method for achieving the advantages and characteristics will become apparent from embodiments described in detail later in conjunction with the accompanying drawings. However, the present disclosure is not limited to the disclosed embodiments, but may be implemented in various different forms. The embodiments are merely provided to complete the present disclosure and to fully notify a person having ordinary knowledge in the art to which the present disclosure pertains, of the category of the present disclosure.

A first, a second, etc. are used to describe various components, but the components are not restricted by the terms. The terms are used to only distinguish one component from the other components. Accordingly, a first component that is described hereinafter may be a second component within the technical spirit of the present disclosure.

Throughout the specification, the same reference numeral denotes the same component.

Characteristics of several embodiments of the present disclosure may be partially or entirely coupled or combined and may be technically variously associated and driven as may be sufficiently understood by those skilled in the art. The embodiments may be independently implemented and may be implemented in an associative relation.

Meanwhile, a potential effect that has not been specifically mentioned in the specification of the present disclosure and that may be expected by technical characteristics of the present disclosure is treated as if it has been described in this specification. The present embodiment has been provided to a person having ordinary knowledge in the art to more fully describe the present disclosure. Contents illustrated in the drawings may be exaggerated and represented compared to an implementation form of an actual invention. A detailed description of a component will be omitted or described in brief if it is deemed to make the subject matter of the present disclosure unnecessarily vague.

Hereinafter, embodiments of the present disclosure are described in detail with reference to the accompanying drawings.

In the present disclosure, an “electronic device” may refer to an apparatus to which an electronic product package according to a disclosed embodiment of the present disclosure is applied.

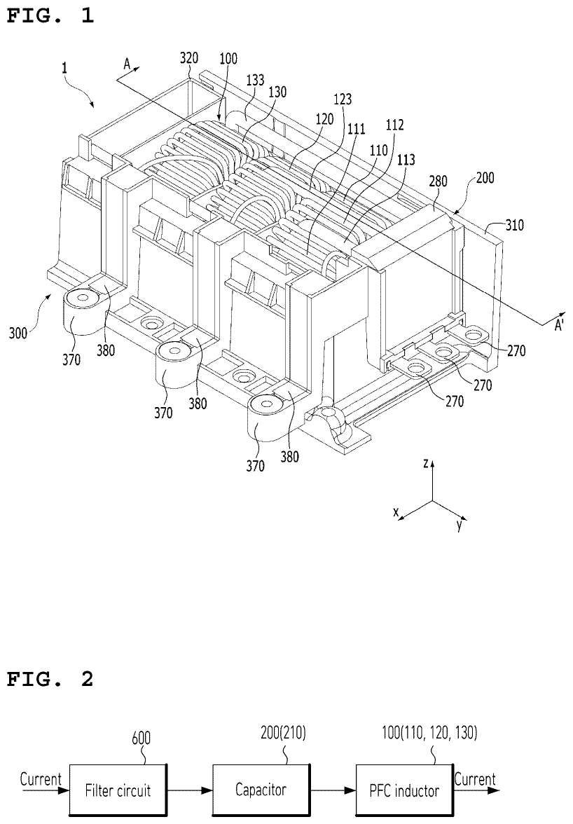

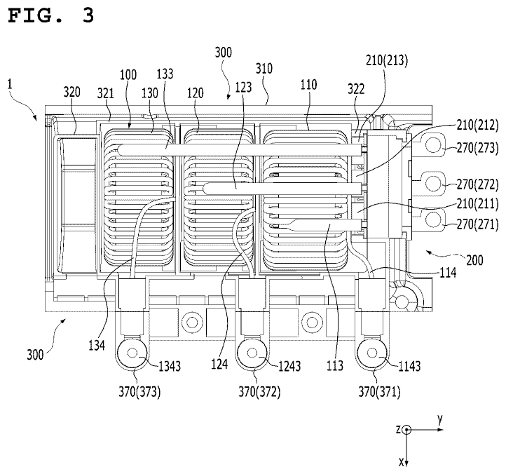

FIG. 1 is a perspective view of an electronic product package for noise correction according to a disclosed embodiment of the present disclosure. FIG. 2 is for describing a flow of a current and a location where a capacitor is disposed in the electronic product package for noise correction of FIG. 1.

Referring to FIG. 1, an electronic product package 1 for noise correction according to a disclosed embodiment of the present disclosure includes a PFC part 100, a capacitor module 200, and a casing 300.

The PFC part 100 may have a construction for improving the power factor of external power that is received from the outside. Illustratively, the PFC part 100 may be an inductor. Invalid power can be minimized from power that is transferred to an electronic device and the power factor can be improved to approach 1 because the power passes through the PFC part 100.

The capacitor module 200 may be disposed on one side of the PFC part 100, and may transfer power supplied from the outside to the PFC part 100. In a process of the power supplied from the outside being transferred to the PFC part 100, noise generated by the power can be reduced. Illustratively, the capacitor module 200 may perform a role of removing electromagnetic wave noise that occurs when power supplied from the outside is subjected to power factor correction by applying only the PFC part 100.

The casing 300 accommodates the PFC part 100 and the capacitor module 200 so that components of the electronic product package 1 for noise correction according to a disclosed embodiment of the present disclosure may form an integrated package. Illustratively, an accommodation space for accommodating the PFC part 100 may be formed in at least a part of the casing 300. An accommodation space for accommodating the capacitor module 200 may be formed in the remaining part of the casing 300.

Referring to FIG. 2, power supplied from the outside (or a current that is generated by corresponding power) passes through the capacitor module 200 or a capacitor 210, that is, one component of the capacitor module 200, via a filter circuit 600. The power (or a current) that passes through the capacitor module 200 or the capacitor 210 passes through the PFC part 100 or PFC inductors 110, 120, and 130, that is, components of the PFC part 100, and may be supplied to components of an electronic device, which requires power.

Detailed components of the PFC part 100, the capacitor module 200, and the casing 300, that is, components of the electronic product package 1 according to a disclosed embodiment of the present disclosure, are described later.

Hereinafter, detailed components of at least some components of the electronic product package 1 according to a disclosed embodiment of the present disclosure are described in detail.

First, the PFC part 100, that is, one component of the electronic product package 1 for noise correction according to a disclosed embodiment of the present disclosure, is described in detail.

FIG. 3 is a top view of the electronic product package for noise correction according to FIG. 1.

Referring to FIGS. 1 and 3, the electronic product package 1 for noise correction according to a disclosed embodiment of the present disclosure includes the PFC part 100. The PFC part 100 may include the one or more PFC inductors 110, 120, and 130. More specifically, the number of PFC inductors 110, 120, 130 may be determined depending on the type of circuit of the electronic product package 1 for noise correction according to a disclosed embodiment of the present disclosure. Illustratively, if the electronic product package 1 for noise correction according to a disclosed embodiment of the present disclosure has a single-phase circuit, the PFC part 100 may be formed to have one PFC inductor 110, 120, or 130. As another example, if the electronic product package 1 for noise correction according to a disclosed embodiment of the present disclosure has a 3-phase circuit, the PFC part 100 may be formed to have three PFC inductors 110, 120, and 130. In the accompanying drawings attached in order to illustratively describe a disclosed embodiment of the present disclosure, the PFC part 100 has been illustrated as having the three PFC inductors 110, 120, and 130, but the present disclosure is not essentially limited thereto. As described above, the corresponding number of PFC inductors 110, 120, and 130 may be provided depending on the type of circuit.

The PFC inductor 110, 120, 130 may include a coil part 111, 121, 131. The coil part 111, 121, 131 may have an annular shape. Illustratively, the coil part 111, 121, 131 may each be a toroid coil. If the coil part 111, 121, 131 is the toroid coil, the number of windings of an electric line that is required to obtain constant inductance is smaller, and the PFC part 100 can be reduced in size. Furthermore, unintended mutual inductance with another element can be reduced.

The PFC inductor 110, 120, 130 may include a winding part 112, 122, 132. The winding parts 112, 122, 132 may form a winding structure centering around the coil part 111, 121, 131. Inductance may be generated due to the winding structure of the winding part 112, 122, 132. Accordingly, the power factor of power that passes through the PFC inductor 110, 120, 130 can be improved to approach 1.

Furthermore, the PFC inductor 110, 120, 130 may include a first connection part 113, 123, 133 corresponding to one end of the winding part 112, 122, 132 and a second connection part 114, 124, 134 corresponding to the other end of the winding part 112, 122, 132. Through the first connection part 113, 123, 133 and the second connection part 114, 124, 134, one end of the PFC inductor 110, 120, 130 may be connected to the filter circuit 600 through at least a part of the capacitor module 200, and the other end of the PFC inductor 110, 120, 130 may be connected to at least one output terminal 370 on a side different from the capacitor module 200 on the basis of the PFC inductor 110, 120, 130. More specifically, the first connection part 113, 123, 133 may be electrically connected to the filter circuit 600 and the outside through the capacitor module 200. The second connection parts 114, 124, and 134 may be electrically connected to a main PCB (not illustrated) through the output terminal 370 of the casing 300 described later, and may supply power to other elements of an electronic device including the electronic product package 1 for noise correction according to a disclosed embodiment of the present disclosure.

Each of the first connection parts 113, 123, and 133 may include a first connection wire 1131 and an insulating part 1132. The first connection wire 1131 enables electrical coupling to be formed. The insulating part 1132 can minimize the occurrence of a short circuit and/or electromagnetic interference at another part by the wire.

The PFC inductors 110, 120, and 130 may be formed to have the same specifications, but the present disclosure is not essentially limited thereto and may be formed to have different sizes, the different numbers of windings, and different materials, etc. for optimal power factor correction for power that is transferred on each phase, if necessary.

Hereinafter, the capacitor module 200, that is, one component of the electronic product package 1 for noise correction according to a disclosed embodiment of the present disclosure, is described in detail.

Referring to FIGS. 1 to 3, the electronic product package 1 for noise correction according to a disclosed embodiment of the present disclosure may include the capacitor module 200. The capacitor module 200 may remove noise that occurs due to external power that is transferred to the PFC part 100 through the filter circuit 600. More specifically, the capacitor module 200 may include the at least one capacitor 210 corresponding to the PFC inductor 110, 120, 130 included in the PFC part 100. Illustratively, if the electronic product package 1 for noise correction according to a disclosed embodiment of the present disclosure has a single-phase circuit, the PFC part 100 has the first PFC inductor 110, and the capacitor module 200 may be formed to include a first capacitor 211 disposed between the filter circuit 600 and the first PFC inductor 110. As another example, if the electronic product package 1 for noise correction according to a disclosed embodiment of the present disclosure has a 3-phase circuit, the PFC part 100 has the first PFC inductor 110, the second PFC inductor 120, and the third PFC inductor 130, and the capacitor module 200 may be formed to include the first capacitor 211 disposed between the filter circuit 600 and the first PFC inductor 110, a second capacitor 212 disposed between the filter circuit 600 and the second PFC inductor 120, and a third capacitor 213 disposed between the filter circuit 600 and the third PFC inductor 130. That is, each capacitor 210 is disposed between the filter circuit 600 and each of the PFC parts 110, 120, and 130, and may remove noise that occurs due to external power that is transferred through the filter circuit 600.

The capacitor 210 included in the capacitor module 200 may be a Y-capacitor. The Y-capacitor may perform a role of suppressing common mode interference, and can remove common mode noise of the electronic product package 1 for noise correction according to a disclosed embodiment of the present disclosure.

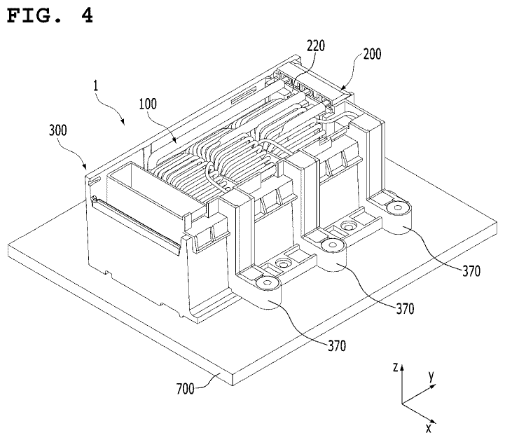

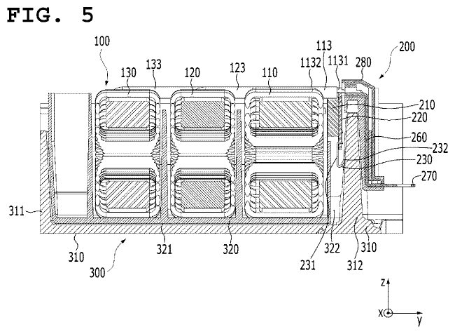

FIG. 4 is for describing a relation between a main PCB on which the electronic product package for noise correction is seated and a PCB on which the capacitor is seated in FIG. 1.

Referring to FIGS. 1 to 4, the capacitor module 200 may include a PCB 220 on which the capacitor 210 is installed. The PCB 220 may form a constant arrangement relation with a main PCB 700 that is electrically connected to the output terminal 370 by the second connection parts 114, 124, and 134 of the PFC part 100. Illustratively, the electronic product package 1 for noise correction according to a disclosed embodiment of the present disclosure may be integrated by the casing 300 and seated on the main PCB 700. The main PCB 700 may form electrical coupling with the output terminal 370. The PFC part 100 may transfer power that has been subjected to power factor correction to other elements of an electronic device through the main PCB 700. In this case, in a conventional technology, common mode noise is removed in a way to additionally dispose the capacitor 210 on the main PCB 700, and an additional space in which the capacitor 210 will be disposed on the main PCB 700 is required. Unlike in the conventional technology, the electronic product package 1 for noise correction according to a disclosed embodiment of the present disclosure includes the capacitor module 200 having the PCB 220, that is, a sub-PCB that is formed by being physically isolated from the main PCB 700. Accordingly, there are advantages in that a space that is occupied by components for removing common mode noise can be minimized and the electronic product package 1 for noise correction according to a disclosed embodiment of the present disclosure is reduced in size within an electronic device.

More specifically, in the electronic product package 1 for noise correction according to a disclosed embodiment of the present disclosure, the PCB 220, that is, one component of the capacitor module 200, may be disposed in a direction in which the PCB is mutually perpendicular to the main PCB 700. As illustrated in FIG. 4, the PCB 220 may be assembled to be erect in the electronic product package 1 for noise correction according to a disclosed embodiment of the present disclosure. A space occupied by the capacitor module 200 can be minimized by a shape in which the PCB 220 is assembled within the electronic product package 1 for noise correction. Accordingly, there are advantages in that the electronic product package 1 for noise correction according to a disclosed embodiment of the present disclosure can be reduced in size and an electronic device including the electronic product package 1 can also be designed to have a small size.

Hereinafter, the casing 300, that is, one component of the electronic product package 1 for noise correction according to a disclosed embodiment of the present disclosure, is described in detail.

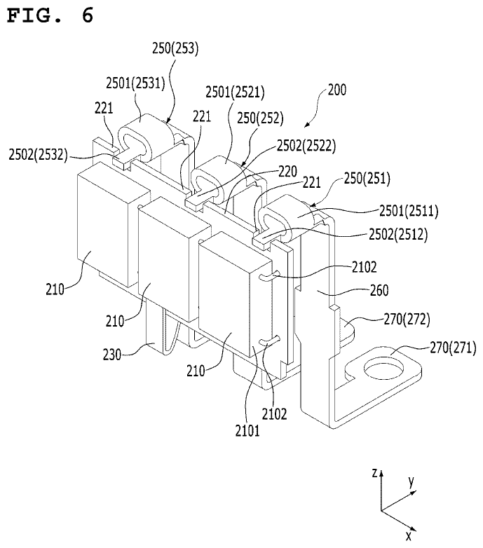

FIG. 5 is a cross-sectional view taken along line A-A′ in FIG. 1.

Referring to FIGS. 1 to 5, the electronic product package 1 for noise correction according to a disclosed embodiment of the present disclosure includes the casing 300. The casing 300 may form an integrated package by accommodating the PFC unit 100 and the capacitor module 200.

The casing 300 may have a dual structure. More specifically, the casing 300 may include a first casing 310 and a second casing 320. The first casing 310 may form an external surface of the casing 300, and may be made of a first material. Furthermore, the second casing 320 may be accommodated within the first casing 310 so that an external surface of the second casing 320 comes into contact with an internal surface of the first casing 310. The second casing 320 may be made of a second material different from the material of the first casing 310. Illustratively, the first casing 310 may be made of an aluminum material, and the second casing 320 may be a plastic bobbin made of a plastic material. As the casing 300 is formed to have the dual structure of the first casing 310 and the second casing 320 as described above, the casing 300 can be reduced in weight and a noise movement path (or a frame ground) for removing common mode noise, which is described later, can be formed. In particular, the first material for forming the first casing 310 is an electrically conductive material. The first casing 310 is electrically connected to the capacitor module 200, and may embody a frame ground FG because the first casing can form the noise movement path. The removal of common mode noise by the capacitor module 200 and the first casing 310 is described later.

Furthermore, the first casing 310 is made of a material having high thermal conductivity, and enables heat generated by operations of the PFC part 100 and the capacitor module 200 to be effectively discharged to the outside.

Hereinafter, a process of common mode noise being removed by the capacitor module 200 and the first casing 310 of the casing 300 is described by using the capacitor module 200 and detailed components of the casing 300.

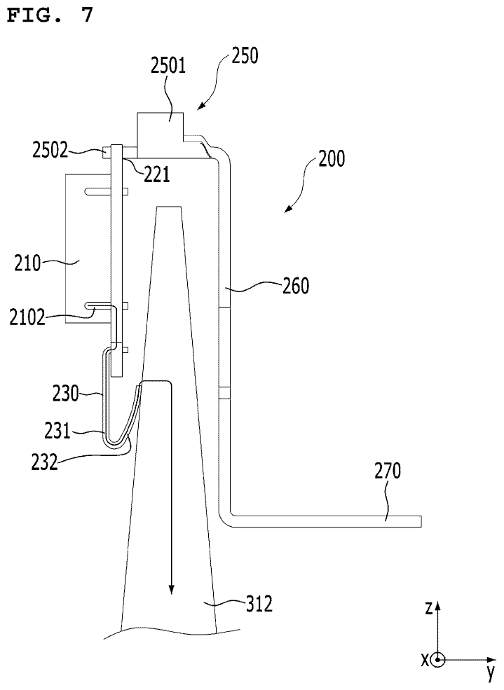

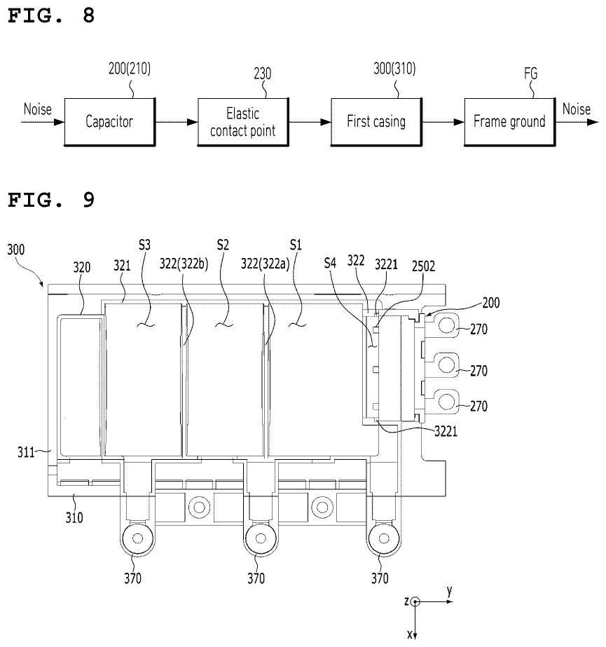

FIG. 6 is for describing the capacitor module 200, that is, one component of the electronic product package for noise correction according to a disclosed embodiment of the present disclosure. FIG. 7 is for describing a path from which noise is removed though at least a part of the capacitor module 200 of FIG. 6 and the casing 300. FIG. 8 is for describing a path from which noise is removed.

Referring to FIGS. 1, 3, and 5 to 8, at least a part of the capacitor module 200, that is, one component of the electronic product package 1 for noise correction according to a disclosed embodiment of the present disclosure, may be electrically connected to come into contact with the first casing 310. More specifically, the capacitor module 200 may further include an elastic contact point 230. One end of the elastic contact point 230 is electrically connected to the capacitor 210 and the other end of the elastic contact point 230 is electrically connected to the internal surface of the first casing 310, and thus may form at least a part of a noise movement path. In this case, the elastic contact point 230 may be made of an electrically conductive material, and acts as a noise movement path along which common mode noise occurring due to external power is removed.

Illustratively, the elastic contact point 230 may include a plane part 231 that is formed by extending from one side of the PCB 220 at a predetermined length in one direction and a curved part 232 that is formed by extending from one end of the plane part 231 and that has a curved shape. That is, the plane part 231 of the elastic contact point 230 may have a structure in which the plane part extends and protrudes from the PCB 220. The curved part 232 of the elastic contact point 230 may have a structure in which the curved part forms an arch toward the plane part 231. When the capacitor module 200 is accommodated in the casing 300, the curved part 232 of the elastic contact point 230 may be pressurized in a direction in which the plane part 231 is formed (e.g., in FIGS. 5 and 7, in a negative direction in a y axis). As the curved part 232 is pressurized by the internal surface of the first casing 310, the elastic contact point 230 and the first casing 310 may form a stable electrical connection structure, and common mode noise can be stably removed.

More specifically, the capacitor 210, that is, one component of the capacitor module 200, may include a capacitor body 2101 and a pair of leads 2102. Any one of the pair of leads 2102 may have a structure in which the pair of leads is connected for each phase. Furthermore, the other of the pair of leads 2102 may be short-circuited in the PCB 220 and connected to the elastic contact point 230. Accordingly, as illustrated in FIG. 8, the common mode noise may move to the internal surface (the internal surface of the second frame part 312) of the first casing 310, which comes into contact with the curved part of the elastic contact point 230 through the elastic contact point 230 from the capacitor 210, so that the frame ground FG is embodied. Accordingly, there is an advantage in that a signal having minimized noise and power having an improved power factor can be supplied to an electronic device because the electronic product package 1 for noise correction according to a disclosed embodiment of the present disclosure is used.

Hereinafter, another detailed structure of the capacitor module 200 and an electrical connection structure with the PFC inductor 110, 120, 130 through the another detailed structure are described.

In the electronic product package 1 for noise correction according to a disclosed embodiment of the present disclosure, the capacitor module 200 may include a wire accommodation part 250. The wire accommodation part 250 may be fixed to one side of the PCB 220, and may accommodate the first connection part 113, 123, 133 for enabling the PFC inductor 110, 120, 130 to be electrically connected to the capacitor module. The first connection part 113, 123, 133 accommodated by the wire accommodation part 250 may be electrically connected to an input terminal 270 through a terminal connection part 260. The corresponding numbers of wire accommodation parts 250, terminal connection parts 260, and input terminals 270 may be provided in a one-to-one way so that they correspond to the number of PFC inductors 110, 120, 130 and the number of capacitors 210. Illustratively, the wire accommodation part 250 may include a first wire accommodation part 251 for accommodating the first connection part 113 of the first PFC inductor 110, a second wire accommodation part 252 for accommodating the second connection part 123 of the second PFC inductor 120, and a third wire accommodation part 253 for accommodating the third connection part 133 of the third PFC inductor 130.

The first wire accommodation part 251 may be electrically connected to the first input terminal 271. The second wire accommodation part 252 may be electrically connected to the second input terminal 272. The third wire accommodation part 253 may be electrically connected to the third input terminal 273.

Hereinafter, detailed components of the wire accommodation part 250 are described more specifically. The wire accommodation part 250 may include a wire cover part 2501. The wire cover part 2501 may be formed to have a hollow structure having a constant thickness in order to cover at least a part of the external surface of the first connection part 113, 123, 133. The first connection part 113, 123, 133 may be accommodated in the wire accommodation part 250 without breaking away from a constant area by the inner circumferential surface of the wire cover part 2501. Furthermore, an electrically stable structure can be formed because interference between the first connection parts 113, 123, and 133 is prevented. Illustratively, the wire cover part 2501 may have a hollow structure having a cylindrical shape, but a shape of the wire cover part 2501 is not limited to the illustrated shape.

Furthermore, the wire accommodation part 250 may include a wire guide part 2502. The wire guide part 2502 may protrude from one surface of the wire cover part 2501 at a predetermined length, and may be fixed to the PCB 220. Furthermore, the wire guide part 2502 may guide the first connection part 113, 123, 133 toward the wire cover part 2501, and can prevent the first connection part 113, 123, 133 from erroneously coming into contact with the PCB 220. The PCB 220 may include a PCB depression part 221 for accommodating the wire guide part 2502. A space occupied by the wire guide part 2502 can be minimized because the wire guide part 2502 is accommodated in the PCB depression part 221.

Hereinafter, a structure in which the PFC part 100 and the capacitor module 200 are accommodated in the casing 300 is described in detail.

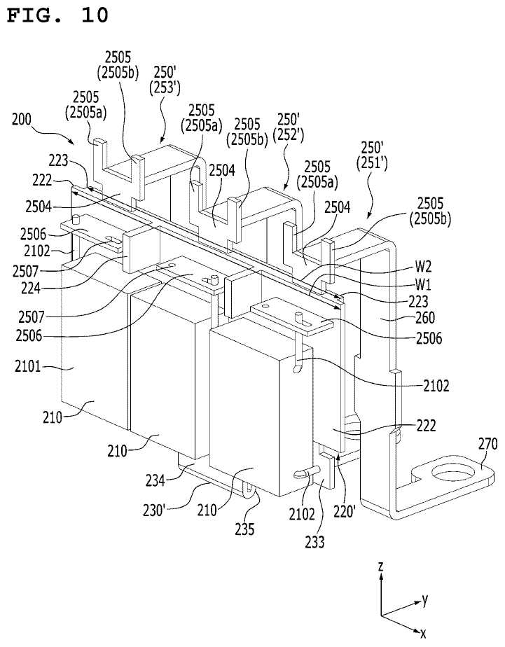

FIG. 9 is for describing the casing 300 that accommodates the PFC part 100 and the capacitor module 200 in the electronic product package 1 for noise correction according to a disclosed embodiment of the present disclosure. FIG. 9 illustrates accommodation spaces of the casing 300 except parts of the PFC part 100 and the capacitor module 200 in order to illustrate the accommodation spaces.

Referring to FIGS. 1, 3, 5, and 9, the casing 300, that is, one component of the electronic product package 1 for noise correction according to a disclosed embodiment of the present disclosure, may form a dual structure. The second casing 320 may accommodate the PFC part 100 and the capacitor module 200. Illustratively, the second casing 320 may include a PFC part accommodation part 321 for accommodating the PFC part 100 and a capacitor module accommodation part 322 for accommodating the capacitor module 200. More specifically, the PFC part accommodation part 321 may accommodate the PFC inductor 110, 120, 130. The capacitor module accommodation part 322 may be formed on one side of the PFC part accommodation part 321, and may accommodate at least a part of the capacitor module 200. A part of the capacitor module 200 may extend over the capacitor module accommodation part 322.

The PFC part accommodation part 321 may include a PFC inductor accommodation space S1, S2, S3, the number of which corresponds to the number of PFC inductors 110, 120, 130. Illustratively, if one PFC inductor 110, 120, 130 is provided and a single-phase circuit is constructed, the PFC part accommodation part 321 may include one PFC inductor accommodation space. As another example, the first PFC inductor accommodation space S1 that accommodated the first PFC inductor 110, a second PFC inductor accommodation space S2 that accommodates the second PFC inductor 120, and a third PFC inductor accommodation space S3 that accommodates the third PFC inductor 130 may be provided.

If the PFC inductor 110, 120, 130 is provided in a plural number, the PFC inductor accommodation space S1, S2, S3 of the PFC part accommodation part may also be provided in a plural number. The PFC part accommodation part 321 may include at least one inductor barrier rib part 322a, 322b that separates the PFC inductors 110, 120, 130. Illustratively, if a 3-phase circuit is constructed and three PFC inductors 110, 120, and 130 are provided, the PFC part accommodation part 321 may include a first inductor barrier rib part 322a that separates the first PFC inductor 110 and the second PFC inductor 120 and a second inductor barrier rib part 322b that separates the second PFC inductor 120 and the third PFC inductor 130. There are advantages in that electromagnetic interference between the PFC inductors 110, 120, and 130 can be minimized by the inductor barrier rib part 322a, 322b and a stable operation of the electronic product package is possible.

The capacitor module accommodation part 322 includes a capacitor module accommodation space S4 that accommodates at least a part of the capacitor module 200. The capacitor 210 and a part of the PCB 220 may be accommodated in the capacitor module accommodation space S4. As the capacitor 210 and the PCB 220 are accommodated in the capacitor module accommodation space S4, the capacitor 210 and the PCB 220 can be safely protected against an external impact and vibration.

In particular, the second casing 320 including the capacitor module accommodation part 322 may further include a PCB accommodation part 3221 that is formed by being depressed at a constant depth. One end of the PCB 220 may be slid downward from the electronic product package 1 for noise correction according to a disclosed embodiment of the present disclosure and may be assembled and fixed to the PCB accommodation part 3221. Accordingly, the PCB 220 can be stably fixed by the second casing 320. The elastic contact point 230 formed by extending from one side of the PCB 220 can be stably brought into contact with the internal surface of the first casing 310.

Furthermore, in the electronic product package 1 for noise correction according to a disclosed embodiment of the present disclosure, the capacitor module 200 may further include a capacitor module cover 280 for protecting the first connection part 113, 123, 133 of the PFC inductor 110, 120, 130 against an outside environment. The casing 300 may further include a casing cover 380 for protecting the second connection part 114, 124, 134 of the PFC inductor 110, 120, 130 against an outside environment. Through the capacitor module cover 280 and the casing cover 380, there are advantages in that a loss attributable to leakage can be minimized and the efficient transfer of power, etc. are possible when power (or a current) is moved through the first connection part 113, 123, 133 and the second connection part 114, 124, 134.

Hereinafter, an electronic product package for noise correction according to another embodiment of the present disclosure is described. In describing components of the electronic product package for noise correction according to another embodiment of the present disclosure, the same components as those of the electronic product package for noise correction according to the embodiment of the present disclosure are described in brief or a description thereof is omitted.

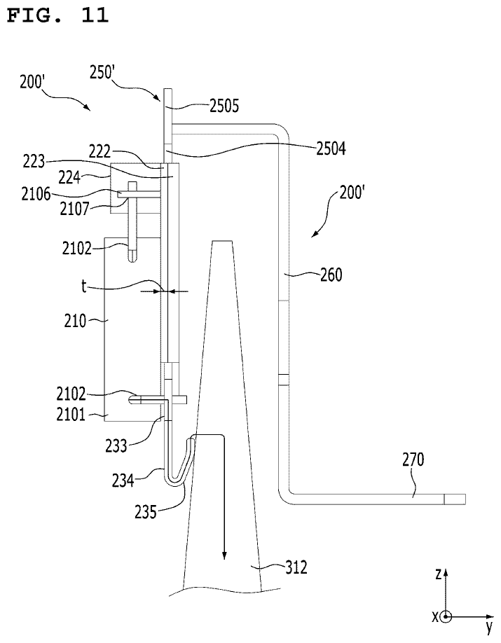

FIG. 10 is for describing a capacitor module 200′, that is, one component of an electronic product package 2 for noise correction according to another embodiment of the present disclosure. FIG. 11 is the side of the capacitor module 200′, that is, one component of the electronic product package 2 for noise correction according to another embodiment of the present disclosure.

Referring to FIGS. 10 and 11, the electronic product package 2 for noise correction according to another embodiment of the present disclosure includes the PFC part 100 and the casing 300 similar to the electronic product package 1 for noise correction according to the embodiment of the present disclosure. In this case, the electronic product package 2 for noise correction according to another embodiment of the present disclosure may include the capacitor module 200′ that is partially different from the electronic product package 1 according to the embodiment of the present disclosure.

In the electronic product package 2 for noise correction according to another embodiment of the present disclosure, the capacitor module 200′ may include a capacitor arrangement board 220′. At least one capacitor 210 corresponding to the PFC inductor 110, 120, 130 may be disposed on one surface of the capacitor arrangement board 220′. The capacitor arrangement board 220′ may be a component that is partially similar to the PCB 220 of the electronic product package 1 for noise correction according to an embodiment of the present disclosure. For example, the capacitor arrangement board 220′ may be disposed in a direction in which the capacitor arrangement board is mutually perpendicular to the main PCB 700. As described above, the capacitor arrangement board 220′ may be assembled to be erect in the electronic product package 2 for noise correction according to another embodiment of the present disclosure. A space occupied by the capacitor module 200′ can be minimized by a shape in which the capacitor arrangement board 220′ is assembled within the electronic product package 2 for noise correction. Accordingly, there are advantages in that the electronic product package 2 for noise correction according to another embodiment of the present disclosure can be reduced in size and an electronic device including the electronic product package 2 can also be designed to have a small size.

However, unlike the PCB 220 on which an electrically conductive pattern has been printed, the capacitor arrangement board 220′ may be made of a material having low electrical conductivity. Illustratively, the capacitor arrangement board 220′ may be made of plastic. Furthermore, unlike the PCB 220, the capacitor arrangement board 220′ does not form a noise movement path. Instead, the capacitor arrangement board 220′ can be rapidly mass-produced through insert injection, etc. and has a low product cost. Accordingly, there are advantages in that a product cost for the electronic product package 2 for noise correction according to another embodiment of the present disclosure can be reduced.

Hereinafter, a wire accommodation and guide unit 250′, that is, one component of the capacitor module 200′, is described.

Referring to FIGS. 10 and 11, in the electronic product package 2 for noise correction according to another embodiment of the present disclosure, the capacitor module 200′ may include a wire accommodation and guide unit 250′. The wire accommodation and guide unit 250′ may accommodate and guide the first connection part 113, 123, 133 that enable the PFC inductor 110, 120, 130 to be connected to the capacitor module 200′.

More specifically, the wire accommodation and guide unit 250′ may include a wire support part 2504 and a pair of wire anti-breakaway parts 2505. The wire support part 2504 may be formed by protruding from one side of the capacitor arrangement board 220′ at a predetermined first height in order to support at least a part of the first connection part 113, 123, 133. Illustratively, the wire support part 2504 may be formed by protruding upward (e.g., a positive direction in a z axis) from the top of the capacitor arrangement board 220′ at a first height, and may function to support the bottom of the first connection part 113, 123, 133.

Referring to FIG. 10, a cross section of the wire support part 2504 may be formed to be an English character T shape, but the present disclosure is not essentially limited thereto and a shape of the wire support part may be modified and applied depending on structural and functional needs.

The wire anti-breakaway part 2505 may be formed by protruding upward (e.g., the positive direction in a z axis) from the top of the wire support part 2504 at a predetermined second height. Illustratively, the wire anti-breakaway part 2505 may be formed integrally with the wire support part 2504, and may be formed by extending from the wire support part 2504. As another example, the wire anti-breakaway part 2505 is formed separately from the wire support part 2504, but may be formed by being combined with the wire support part 2504.

The wire anti-breakaway part 2505 may include a first wire anti-breakaway part 2505a and a second wire anti-breakaway part 2505b. Illustratively, the wire anti-breakaway part 2505 may be formed on both sides of the first connection part 113, 123, 133 so that the first connection part 113, 123, 133 accommodated in the wire accommodation and guide unit 250′ is not detached from the wire accommodation and guide unit 250′. By the structure of the wire support part 2504 and the wire anti-breakaway part 2505, a cross section of the wire accommodation and guide unit 250′ may be formed in an English character Y shape. Accordingly, there is an advantage in that the first connection part 113, 123, 133 can be stably disposed in the wire accommodation and guide unit 250′ at a proper location.

In the electronic product package 2 for noise correction according to another embodiment of the present disclosure, the wire accommodation and guide unit 250′ may be formed to be connected to the terminal connection part 260 and the input terminal 270. The first connection part 113, 123, 133 may be formed at least one of the wire accommodation and guide unit 250′ and the terminal connection part 260 through welding coupling or soldering coupling. Accordingly, a signal that is input through the input terminal 270 can flow into the PFC parts 110, 120, and 130 and the capacitor 210.

Furthermore, the wire accommodation and guide unit 250′ may further include a lead accommodation part 2506. The lead accommodation part 2506 may be formed by extending from a side opposite to the wire anti-breakaway part 2505 in the wire support part 2504, and may be formed by protruding from one surface of the capacitor arrangement board 220′ at a predetermined length. Illustratively, the lead accommodation part 2506 may be formed by protruding from one surface of the capacitor arrangement board 220′ at a predetermined length on a zx plane in one direction (e.g., a negative direction in a y axis). In this case, the protruded length of the lead accommodation part 2506 may be formed to have a length to the extent that the protruded length does not fall outside a space in which the capacitor module 200′ is accommodated while a lead 2102 of the capacitor 210 is not excessively bent.

The lead accommodation part 2506 may include at least one lead accommodation hole 2507 that accommodates the lead 2102 of the capacitor 210 or has the lead penetrate therethrough on one surface thereof in order to accommodate the lead 2102 of the capacitor 210. Illustratively, the lead accommodation hole 2507 may have a shape corresponding to a cross-sectional shape of the lead 2102 or may have a shape larger than a cross section of the lead 2102. There are advantages in that a signal transferred through the input terminal 270 can be stably moved to the capacitor 210 through the lead accommodation part 2506 of the wire accommodation and guide unit 250′ and common mode noise can be stably moved because the lead accommodation hole 2507 accommodates the lead 2102 and/or the lead penetrates the lead accommodation hole.

Hereinafter, structural characteristics of the capacitor arrangement board 220′ are additionally described.

Referring to FIGS. 10 and 11, the capacitor arrangement board 220′, that is, one component of the electronic product package 2 for noise correction according to another embodiment of the present disclosure, may include a first board step part 222 and a second board step part 223. The first board step part 222 may be a component that has a first board width w1 and has the capacitor 210 disposed on one surface side thereof. The second board step part 223 may have a second board width w2, and may be formed by protruding in another direction (e.g., a positive direction in the y axis) from the other surface side of the first board step part 222, which is opposite to one surface side on which the capacitor is disposed, at a predetermined thickness. Furthermore, the second board width w2 of the second board step part 223 may be formed to be smaller than the first board width w1 of the first board step part 222. Both ends of the first board step part 222 may be stably accommodated and fixed within the second casing 320 of the casing 300. There are advantages in that the capacitor arrangement board 220′ can be easily molded and the possibility that a shape of the capacitor arrangement board is modified and applied is improved because the capacitor arrangement board is made of a common plastic material not a PCB.

Referring to FIGS. 9 to 11, the casing 300, that is, one component of the electronic product package 2 for noise correction according to another embodiment of the present disclosure, may include a first casing 310 and a second casing 320, and may further include a board accommodation part 3221 that corresponds to the PCB accommodation part (3221 in FIG. 9) in the capacitor module accommodation part 322 included in the second casing 320 and that is depressed and formed in the second casing 320 at a constant depth. That is, the PCB accommodation part 3221 illustrated in FIG. 9 may be used as the board accommodation part 3221 which may accommodate the capacitor arrangement board 220′, that is, one component of the electronic product package 2 for noise correction according to another embodiment of the present disclosure.

The first board step part 222 may have both ends accommodated in the board accommodation part 3221 in a width direction thereof, which is depressed and formed in the second casing 320 of the casing 300 at a constant depth. The second board step part 223 may have both ends accommodated in the internal surface of the second casing 320 in a width direction thereof. Illustratively, the first board width w1 of the first board step part 222 may correspond to a width (e.g., a length parallel to an x axis) that is generated by the board accommodation part 3221. The second board width w2 of the second board step part 223 may correspond to the width (e.g., the length parallel to the x axis) of the internal surface of the capacitor module accommodation part 322. Furthermore, the thickness t of the first board step part 222 may correspond to the thickness of the board accommodation part 3221 in a length direction thereof. Accordingly, there are advantages in that the capacitor arrangement board 220′ can be stably accommodated and fixed to the capacitor module accommodation part 322 and the stability of the general electronic product package 2 for noise correction is improved because the capacitor arrangement board 220′ is disposed at a proper location within the casing 300.

Meanwhile, in the electronic product package 2 for noise correction according to another embodiment of the present disclosure, the capacitor module 200′ may further include an elastic contact point 230′. As in the electronic product package 1 for noise correction according to an embodiment of the present disclosure, the elastic contact point 230′ may form at least a part of a noise movement path for removing common mode noise. That is, one end of the elastic contact point 230′ may be electrically connected to the capacitor 210 and the other end of the elastic contact point 230′ may be electrically connected to the internal surface of the first casing 310 of the casing 300, thus forming at least a part of the noise movement path.

More specifically, the elastic contact point 230′ may include a common lead accommodation part 233. The common lead accommodation part 233 may be formed by being combined with one surface side of the capacitor arrangement board 220′. The common lead accommodation part 233 may be formed by extending in the width direction (e.g., a positive direction in the x axis and a negative direction in the x axis) so that the lead 2102 of the capacitor 210 is excessively bent. As the common lead accommodation part 233 is formed by widely extending in the width direction, the lead 2102 of the capacitor 210 can be accommodated in the common lead accommodation part 233 and penetrate the common lead accommodation part 233 so that noise can be stably moved.

Furthermore, the elastic contact point 230′ may include a plane part 234 that is formed by extending in one direction (e.g., a negative direction in the z axis) at a predetermined length from one side of the capacitor arrangement board 220′ and a curved part 235 that is formed by extending from one end of the plane part 234 and that has a curved shape. That is, the plane part 234 of the elastic contact point 230′ may have a structure in which the plane part extends and protrudes from the capacitor arrangement board 220′ and is formed by extending downward from the common lead accommodation part 233. The curved part 235 of the elastic contact point 230′ may have a structure in which the curved part forms an arch toward the plane part 234. When the capacitor module 200′ is accommodated in the casing 300, the curved part 235 of the elastic contact point 230′ may be pressurized toward a direction in which the plane part 234 has been formed (e.g., toward the negative direction in the y axis in FIGS. 10 and 11). As the curved part 235 is pressurized by the internal surface of the first casing 310, the elastic contact point 230′ and the first casing 310 may form a stable electrical connection structure, and common mode noise can be stably removed.

More specifically, the capacitor 210, that is, one component of the capacitor module 200′, may include a capacitor body 2101 and a pair of leads 2102. Any one of the pair of leads 2102 may have a structure in which the lead is connected to the wire accommodation and guide unit 250′ for each phase. Furthermore, the other of the pair of leads 2102 may be connected to the common lead accommodation part 233 of the elastic contact point 230′. Accordingly, as illustrated in FIGS. 10 and 11, common mode noise is moved from the capacitor 210 to the internal surface (the internal surface of the second frame part 312) of the first casing 310, which comes into contact with the curved part 235 of the elastic contact point 230′ through the elastic contact point 230′, so that the frame ground FG is embodied. Accordingly, there is an advantage in that a signal having minimized noise and power having an improved power factor can be supplied to an electronic device because the electronic product package 2 for noise correction according to another embodiment of the present disclosure is used.

While the preferred embodiments of the present disclosure have been described above, the present disclosure is not limited to the embodiments, but may be modified and embodied in various ways within the technical scope of the present disclosure, which may also belong to the claims. Industrial Applicability

A disclosed embodiment of the present disclosure provides the electronic product package for noise correction, which minimizes an occupied space because the PFC part and the capacitor module are integrated into a single package.

1. An electronic product package for noise correction, comprising:
a PFC part that improves a power factor of external power that is supplied from an outside;
a capacitor module that transfers the external power to the PFC part and that removes noise occurring in a process of the external power being transferred; and
a casing that forms an integrated package by accommodating the PFC part and the capacitor module.

2. The electronic product package of claim 1, wherein:
the PFC part comprises at least one PFC inductor,
one end of the PFC inductor is connected to a filter circuit through at least a part of the capacitor module, and
the other end of the PFC inductor is connected to at least one output terminal on a side different from a side of the capacitor module on the basis of the PFC inductor.

3. The electronic product package of claim 2, wherein:
the capacitor module comprises at least one capacitor corresponding to the PFC inductor, and
the capacitor is disposed between the filter circuit and the PFC part and removes noise occurring due to the external power transferred through the filter circuit.

4. The electronic product package of claim 3, wherein the casing comprises:
a first casing that is made of a first material and that forms an external surface of the casing; and
a second casing that is made of second material different from the first casing and that is accommodated within the first casing so that an external surface of the second casing comes into contact with an internal surface of the first casing.

5. The electronic product package of claim 4, wherein:
the first material is an electrically conductive material, and
the first casing is electrically connected to the capacitor module and forms a noise movement path.

6. The electronic product package of claim 5, wherein the capacitor module further comprises an elastic contact point that has one end electrically connected to the capacitor and the other end electrically connected to the internal surface of the first casing and that forms at least a part of the noise movement path.

7. The electronic product package of claim 6, wherein:
the elastic contact point comprises a plane part formed by extending from one side of a PCB on which the capacitor is disposed at a predetermined length in one direction and a curved part formed by extending from one end of the plane part and having a curved shape, and
the curved part is assembled into the casing and pressurized by the internal surface of the first casing.

8. The electronic product package of claim 4, wherein the second casing comprises:
a PFC part accommodation part for accommodating the PFC part; and
a capacitor module accommodation part that is formed on one side of the PFC part accommodation part and that accommodates at least a part of the capacitor module.

9. The electronic product package of claim 8, wherein the PFC part accommodation part comprises a PFC inductor accommodation space corresponding to the number of PFC inductors.

10. The electronic product package of claim 9, wherein:
the PFC inductor is provided in a plural number, and
the PFC part accommodation part further comprises at least one inductor barrier rib part that separates the PFC inductors.

11. The electronic product package of claim 3, wherein:
the capacitor module comprises a PCB on which the capacitor is installed, and
the PCB is disposed in a direction in which the PCB is mutually perpendicular to a main PCB that is electrically connected to the output terminal.

12. The electronic product package of claim 11, wherein:
the capacitor module comprises a wire accommodation part that is fixed to one side of the PCB and that accommodates a first connection part that enables the PFC inductor to be connected to the capacitor module, and
the wire accommodation part comprises:
a wire cover part having a constant thickness and a hollow structure in order to cover at least a part of an external surface of the first connection part; and
a wire guide part that is formed by protruding from one surface of the wire cover part at a predetermined length, that is fixed to the PCB, and that guides the first connection part.

13. The electronic product package of claim 4, wherein the second casing further comprises a PCB accommodation part depressed and formed at a constant depth, and
one end of the PCB is slid, assembled, and fixed to the PCB accommodation part.

14. The electronic product package of claim 3, wherein:
the capacitor module comprises a capacitor arrangement board in which the capacitor is disposed, and
the capacitor arrangement board is disposed in a direction in which the capacitor arrangement board is mutually perpendicular to a main PCB that is electrically connected to the output terminal.

15. The electronic product package of claim 14, wherein:
the capacitor module comprises a wire accommodation and guide unit that is formed by extending from one side of the capacitor arrangement board at a predetermined length and that accommodates and guides a first connection part that enables the PFC inductor to be connected to the capacitor module, and
the wire accommodation and guide unit comprises:
a wire support part that is formed by protruding from the one side of the capacitor arrangement board at a predetermined first height in order to support at least a part of an external surface of the first connection part; and
a pair of wire anti-breakaway parts that is formed by protruding upward from a top of the wire support part at a predetermined second height, that is fixed to the capacitor arrangement board, and that guides the first connection part.

16. The electronic product package of claim 15, wherein:
the wire accommodation and guide unit further comprises a lead accommodation part that is formed by extending from a side opposite to the wire anti-breakaway part in the wire support part and that is formed by protruding from one surface of the capacitor arrangement board at a predetermined length, and
the lead accommodation part comprises at least one lead accommodation hole that accommodates the lead of the capacitor or has the lead penetrate therethrough.

17. The electronic product package of claim 14, wherein the capacitor arrangement board comprises:
a first board step part that has a first board width and has the capacitor disposed on one surface side thereof; and
a second board step part that has a second board width smaller than the first board width and that is formed by protruding from the other surface side opposite to one surface side that belongs to the first board step part and in which the capacitor is disposed at a predetermined thickness.

18. The electronic product package of claim 17, wherein:
the first board step part has both ends accommodated in a board accommodation part that is depressed and formed in the second casing of the casing at a constant depth in a width direction thereof, and
the second board step part has both ends accommodated in an internal surface of the second casing in a width direction thereof.

19. The electronic product package of claim 16, wherein:
the capacitor module further comprises an elastic contact point that has one end electrically connected to the capacitor and the other end electrically connected to the internal surface of the first casing of the casing and forms at least a part of a noise movement path, and
the elastic contact point comprises a common lead accommodation part that is formed by being combined with one surface side of the capacitor arrangement board and that accommodates the lead of the capacitor in common.
